(19) United States
(12) Patent Application Publication
(10) Pub. No.: US 2026/0096017 A1
(43) Pub. Date: Apr. 2, 2026

(54) PRINTED CIRCUIT BOARD

(71) Applicant: SAMSUNG ELECTRO-MECHANICS CO., LTD., Suwon-si (KR)

(72) Inventors: Tae Hong MIN, Suwon-si (KR); Jong Eun PARK, Suwon-si (KR)

(73) Assignee: SAMSUNG ELECTRO-MECHANICS CO., LTD., Suwon-si (KR)

(21) Appl. No.: 19/213,465

(22) Filed: May 20, 2025

(30) Foreign Application Priority Data
Oct. 2, 2024 (KR) 10-2024-0133465

(51) Int. Cl. H05K 1/02; H05K 1/03; H05K 1/11; H05K 1/18

(52) U.S. Cl. CPC H05K 1/0271; H05K 1/0306; H05K 1/115; H05K 1/185; H05K 2201/096; H05K 2201/2018

(57) ABSTRACT

The present disclosure relates to a printed circuit board including: a glass layer having upper and lower surfaces opposing each other in a first direction, first and second side surfaces opposing each other in a second direction, and third and fourth side surfaces opposing each other in a third direction, and configured to reinforce at least a portion of an edge region adjacent to each of the first to fourth side surfaces, and configured not to reinforced at least a portion of an inner region surrounded by the edge region; a first insulating material covering at least portions of the first to fourth side surfaces of the glass layer; and second and third insulating materials covering at least a portion of each of the upper surface and the lower surface of the glass layer and extending to an upper side and a lower side of the first insulating material, respectively.

### CROSS-REFERENCE TO RELATED APPLICATION(S)

This application claims benefit of priority to Korean Patent Application No. 10-2024-0133465 filed on Oct. 2, 2024, in the Korean Intellectual Property Office, the disclosure of which is incorporated herein by reference in its entirety.

### TECHNICAL FIELD

The present disclosure relates to a printed circuit board.

Efforts to improve the performance of electronic products are moving beyond semiconductors to packaging, and products utilizing glass substrates, such as large-area substrates for servers, are attracting attention as next-generation technologies. Meanwhile, glass substrates may have advantages over organic substrates formed of epoxy materials in terms of heat dissipation, warpage control, large-area, and microcircuit implementation. However, glass substrates may have problems determined by the occurrence and propagation of cracks during processing or transport thereof. In this case, glass particles may enter the product through various paths such as processing equipment or chemicals, which may lead to product defects. Therefore, it is necessary to solve the problem of cracks or breakage of glass.

### SUMMARY

An aspect of the present disclosure is to provide a printed circuit board including a glass layer, which may effectively prevent cracking or breakage of glass.

One of the various solutions proposed by the present disclosure is to reinforce at least a portion of an edge region of a glass layer and form an insulating material surrounding the glass layer.

For example, a printed circuit board according to an example embodiment may include: a glass layer having an upper surface and a lower surface opposing each other in a first direction, a first side surface and a second side surface opposing each other in a second direction, perpendicular to the first direction, and a third side surface and a fourth side surface opposing each other in a third direction, perpendicular to the first and second directions, and configured to reinforce at least a portion of an edge region adjacent to each of the first to fourth side surfaces, and configured not to reinforced at least a portion of an inner region surrounded by the edge region; a first insulating material covering at least a portion of the first to fourth side surfaces of the glass layer; and second and third insulating materials covering at least a portion of each of the upper surface and the lower surface of the glass layer and extending to an upper side and a lower side of the first insulating material, respectively.

Furthermore, for example, a printed circuit board according to some example embodiments may further include: a frame having a through-portion; a glass layer disposed on the through-portion and configured to reinforce at least a portion of an edge region adjacent to a plurality of side surfaces connecting an upper surface and a lower surface thereof; and an insulating material filling at least a portion of the through-portion and covering at least a portion of each of the frame and the glass layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a cross-sectional view schematically illustrating an example of a printed circuit board;

FIG. 3 is a schematic cut plan view taken along a line of the printed circuit board of FIG. 2;

FIGS. 4A to 4G are process diagrams schematically illustrating an example of manufacturing the printed circuit board of FIG. 2;

FIGS. 5A and 5B are process diagrams schematically illustrating an example of disposing a plurality of glass layers on a frame having a plurality of through-portions;

FIG. 6 is a cross-sectional view schematically illustrating another example of a printed circuit board;

FIG. 7 is a cross-sectional view schematically illustrating another example of a printed circuit board;

FIG. 8 is a cross-sectional view schematically illustrating another example of a printed circuit board; and

FIG. 9 is a cross-sectional view schematically illustrating another example of a printed circuit board.

### DETAILED DESCRIPTION

Hereinafter, the present disclosure will be described with reference to the accompanying drawings. In the drawings, the shape and size of the elements may be exaggerated or reduced for clearer description.

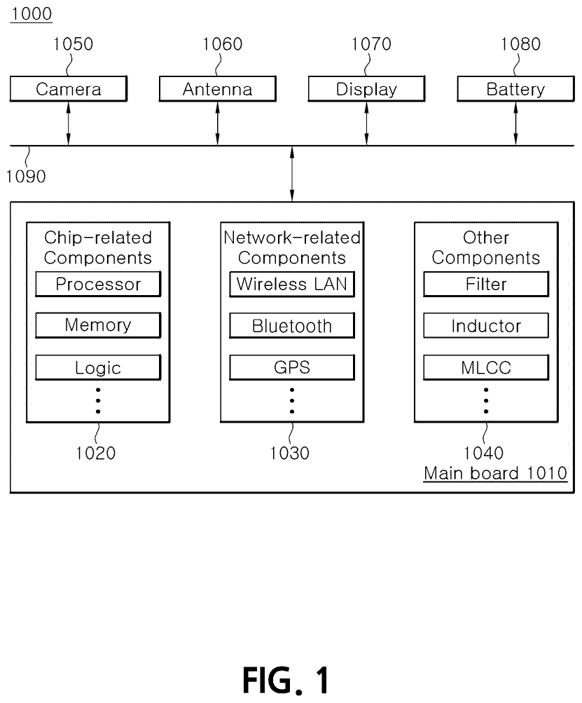

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component, and a server. However, the electronic device 1000 is not limited thereto, and may be any other electronic device that processes data in addition thereto.

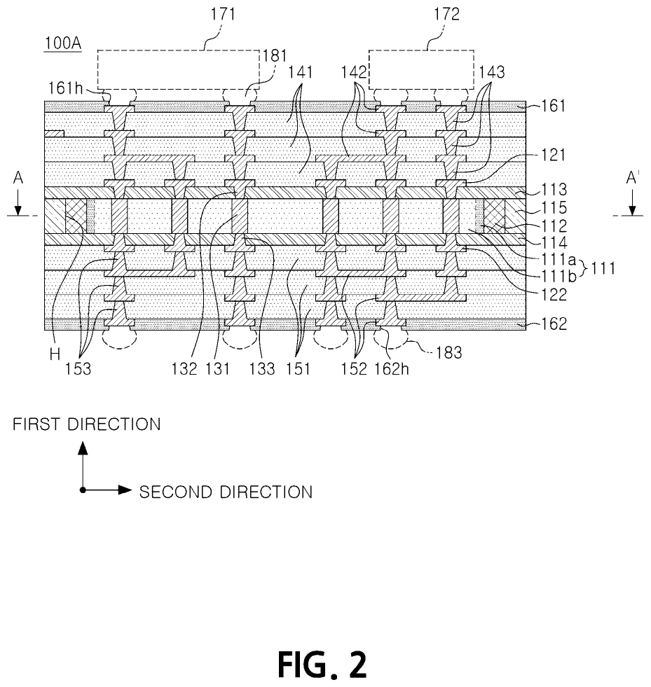

FIG. 2 is a cross-sectional view schematically illustrating an example of a printed circuit board.

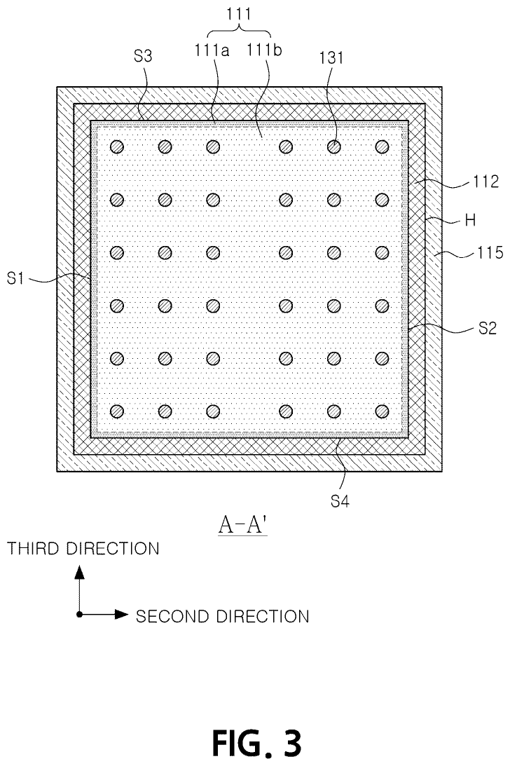

FIG. 3 is a schematic cut plan view taken along a line A-A′ of the printed circuit board of FIG. 2.

Referring to the drawings, a printed circuit board 100A may include a glass layer 111 having an upper surface and a lower surface opposing each other in a first direction, a first side surface S1 and a second side surface S2 opposing each other in a second direction, perpendicular to the first direction, and a third side surface S3 and a fourth side surface S4 opposing each other in a third direction, perpendicular to the first and second directions, a first insulating material 112 covering at least portions of the first to fourth side surfaces S1, S2, S3 and S4 of the glass layer 111, a second insulating material 113 covering at least a portion of the upper surface of the glass layer 111 and extending upwardly from the first insulating material 112, and a third insulating material 114 covering at least a portion of the lower surface of the glass layer 111 and extending downwardly from the first insulating material 112. In the glass layer 111, at least a portion of an edge region 111a adjacent to each of the first to fourth side surfaces S1, S2, S3 and S4 of the glass layer 111 may be reinforced, and at least a portion of an inner region 111b surrounded by the edge region 111a may not be reinforced. For example, only the edge region 111a may be selectively reinforced.

Meanwhile, the reinforcing treatment may be a chemical reinforcing treatment, through which strength of at least a portion of the edge region 111a of the glass layer 111 may be increased. For example, in the chemical reinforcing, in order to selectively reinforce only the edge region 111a in a KNO₃ solution heated to a temperature of about 400° C. to 500° C., the glass layer 111 in which a masking tape is attached to the upper surface and the lower surface thereof, respectively, is deposited to exchange Na⁺ ions with K⁺ ions having a larger volume (or a larger ionic radius), thereby increasing the strength by the compaction effect. Accordingly, first and second metal ions having different ionic radii may exist together in the reinforced region, for example, Na⁺ ions and K⁺ ions may exist together. Compressive stress may occur in the reinforced surface, and an ion exchange penetration depth may be controlled by the process time. For example, the edge region 111a of the glass layer 111 may be reinforced by a depth of about 50 μm to 100 μm from the first to fourth side surfaces S1, S2, S3 and S4 based on the second or third direction by controlling the immersion time, but the present disclosure is not limited thereto. The compressive stress and the reinforcement depth of a reinforced structure may be measured by a change in refraction of light passing through the glass of the edge region 111a.

In this manner, in the printed circuit board 100A, at least a portion of the edge region 111a of the glass layer 111 may be reinforced, but at least a portion of the inner region 111b of the glass layer 111 may not be reinforced. For example, the strength of the edge region 111a, among the edge region 111a and the inner region 111b of the glass layer 111, may be selectively increased. In this case, since the compressive stress is mainly applied to the edge region 111a, chipping and microcracks may be removed, through which bending characteristics may be improved. Meanwhile, at least another portion of the inner region 111b of the glass layer 111 may also be reinforced, but if only the edge region 111a is selectively reinforced and the inner region 111b is barely reinforced, a more excellent crack prevention effect may be achieved in a structure in which the glass layer 111 is covered with the first to third insulating materials 112, 113 and 114 as in the printed circuit board 100A.

Meanwhile, each of the first to third insulating materials 112, 113 and 114 may be an insulating layer in which boundaries thereof are separated from each other. For example, after the first insulating material 112 is formed, the second and third insulating materials 113 and 114 may be additionally formed, and the first insulating material 112 may include a different material from the second and third insulating materials 113 and 114. In this case, an upper surface and a lower surface of the first insulating material 112 may be substantially coplanar with the upper and lower surfaces of the glass layer 111, respectively, and a flatter surface, which may be advantageous to form finer wirings on the second and third insulating materials 113 and 114. However, the present disclosure is not limited thereto, and one or more of the second and third insulating materials 113 and 114 may be integrated with the first insulating material 112 without boundaries to form one insulating layer. For example, the first and second insulating materials 112 and 113 may be formed as one insulating layer, and the third insulating material 114 may include substantially the same insulating material as the first and second insulating materials 112 and 113 and may be integrated with the first and second insulating materials 112 and 113 without boundaries after curing. In this case, the process may be simplified.

Meanwhile, the printed circuit board 100A may further include a frame 115 having a through-portion H in which the glass layer 111 is disposed. The first insulating material 112 may fill the through-portion H which is at least a portion of a space between each of the first to fourth side surfaces S1, S2, S3 and S4 of the glass layer 111 and the wall surface of the frame 115. The second and third insulating materials 113 and 114 may be disposed on an upper side and a lower side of the frame 115, respectively. The frame 115 may include a material having excellent rigidity, may include, for example, copper clad laminate (CCL) or unclad CCL. As described below, the process may be performed on a panel level through the frame 115, and the frame 115 may remain in a final unit, which may be more advantageous for warpage control

Meanwhile, the printed circuit board 100A may further include a through-via 131 penetrating between the upper surface and the lower surface of the glass layer 111, a first connection via 132 penetrating through the second insulating material 112 and connected to an upper side of the through-via 131, a second connection via 133 penetrating through the third insulating material 113 and connected to a lower side of the through-via 131, a first wiring layer 121 disposed on an upper surface of the second insulating material 113 and at least partially connected to the first connection via 132, and a second wiring layer 122 disposed on a lower surface of the third insulating material 114 and at least partially connected to the second connection via 133. The through-via 131 may be a through-glass via (TGV) and may include a seed layer having a multilayer structure formed by a sputtering process. For example, the through-via 131 may include sputtered titanium and sputtered copper. Each of the first and second connection vias 132 and 133 may be a blind via (BV) and may include a seed layer formed by electroless plating. For example, the first and second connection vias 132 and 133 may include chemical copper. The first and second connection vias 132 and 133 may be in direct contact with an upper surface and a lower surface of the through-via 131, respectively. The upper surface and the lower surface of the through-via 131 may be substantially coplanar with the upper surface and the lower surface of the glass layer 111, respectively, but the present disclosure is not limited thereto.

Meanwhile, the printed circuit board 100A may further include a plurality of first build-up insulating layers 141 stacked on the upper surface of the second insulating material 113, a plurality of first build-up wiring layers 142 respectively disposed on or in upper surfaces of the plurality of first build-up insulating layers 141, and a plurality of first build-up via layers 143 respectively disposed in the plurality of first build-up insulating layers 141. Additionally, the printed circuit board 100A may further include a plurality of second build-up insulating layers 151 stacked on the lower surface of the third insulating material 114, a plurality of second build-up wiring layers 152 respectively disposed on or in lower surfaces of the plurality of second build-up insulating layers 151, and a plurality of second build-up via layers 153 respectively disposed in the plurality of second build-up insulating layers 151. An electrical connection path from an uppermost side to a lowermost side of the substrate may be provided through the plurality of first and second build-up wiring layers 142 and 152 and the plurality of first and second build-up via layers 143 and 153. For example, the printed circuit board 100A may include the glass layer 111, and the first to third insulating materials 112, 113 and 114, and the frame 115, as a core layer, and may have a structure built up on both sides of the core layer.

Meanwhile, the printed circuit board 100A may further include a first passivation layer 161 disposed on an upper surface of the first build-up insulating layer 141 on an uppermost side and having a first opening 161h exposing at least a portion of a first build-up wiring layer 142 on an uppermost side, a second passivation layer 162 disposed on a lower surface of a second build-up insulating layer 151 on a lower side and having a second opening 162h exposing at least a portion of the second build-up wiring layer 152 on a lowermost side, a first electrical connection metal 181 disposed on the first opening 161h and connected to the at least exposed portion of the first build-up wiring layer 142 disposed on the uppermost side, a second electrical connection metal 183 disposed on the second opening 162h and connected to the at least exposed portion of the second build-up wiring layer 152 disposed on the lowermost side, and first and second electronic components 171 and 172 respectively mounted on the upper surface of the first passivation layer 161 and respectively connected to the first electrical connection metal 181. For example, the printed circuit board 100A may have a package structure in which components are mounted on a package substrate.

Hereinafter, components of the printed circuit board 100A will be described in more detail with reference to the drawings.

The glass layer 111 may include glass, which is an amorphous solid. The glass may include, for example, pure silicon dioxide (about 100% SiO₂), soda lime glass, borosilicate glass, and aluminosilicate glass. However, the present disclosure is not limited thereto, and an alternative glass material, for example, fluorine glass, phosphate glass, chalcogen glass, or the like, may also be used as the material of the glass layer 111. Additionally, other additives may be further included to form a glass having specific physical properties. The additives may include calcium carbonate (e.g., lime) and sodium carbonate (e.g., soda ash or washing soda), as well as at least one selected from the group consisting of magnesium, calcium, manganese, aluminum, lead, boron, iron, chromium, potassium, sulfur, and antimony, and carbonates and oxides thereof and other elements. The glass layer 111 may be a layer distinct from organic insulating materials including glass fiber (Glass Fiber, Glass Cloth or Glass Fabric), for example, Copper Clad Laminate (CCL), Prepreg (PPG), or the like. For example, the glass layer 111 may include a glass panel capable of implementing a large area, such as a glass plate.

Each of the first to third insulating materials 112, 113 and 114 may include an organic insulating material. The organic insulating material may include a thermosetting resin such as an epoxy resin, a thermoplastic resin such as a polyimide, or a material including an inorganic filler, an organic filler, and/or glass fiber (Glass Fiber, Glass Cloth or Glass Fabric) together with the resin. For example, the organic insulating material may include a non-photosensitive insulating material such as Ajinomoto Build-up Film (ABF), Prepreg (PPG), or the like, but the present disclosure is not limited thereto, and other polymer materials may be used in addition thereto. Additionally, the organic insulating material may include a photosensitive insulating material such as a Photoimageable Dielectric (PID), or an adhesive sheet such as a Bonding Sheet (BS). Meanwhile, the first to third insulating materials 112, 113 and 114 may include substantially the same organic insulating material, or may include different organic insulating materials.

Each of the first and second wiring layers 121 and 122 may include a metal. The metal included in the first and second wiring layers 121 and 122 may include at least one selected from the group consisting of copper (Cu), aluminum (Al), silver (Ag), tin (Sn), gold (Au), nickel (Ni), lead (Pb), titanium (Ti), and alloys thereof. Each of the first and second wiring layers 121 and 122 may perform various functions according to the design. For example, the first and second wiring layers 121 and 122 may include a signal pattern, a power pattern, a ground pattern, etc. Each of the patterns may have various shapes such as a line, a plane, a pad, and the like. The first and second wiring layers 121 and 122 may include an electroless plating layer (or chemical copper) and an electrolytic plating layer (or electrolytic copper).

The through-via 131 may include a metal. The metal may include at least one selected from the group consisting of copper (Cu), aluminum (Al), silver (Ag), tin (Sn), gold (Au), nickel (Ni), lead (Pb), titanium (Ti), and alloys thereof. The through-via 131 may penetrate between the upper surface and the lower surface of the glass layer 111. The upper surface and the lower surface of the through-via 131 may be substantially coplanar with the upper surface and the lower surface of the glass layer 111. The through-via 131 may perform various functions depending on the design. For example, the through-via 131 may include a ground via, a power via, and a signal via. The through-via 131 may have an approximately circular or elliptical shape on a plane, but is not limited thereto, and may have an approximately flower shape on a plane, for example, in terms of securing close contact through an increase in the specific surface area. The through-via 131 may have an approximately rectangular shape in a cross-section, but is not limited thereto, and may have an approximately hourglass shape. The through-via 131 may include a plurality of sputtered layers and electrolytic plating layers (or electrolytic copper). The through-via 131 may be provided in plural.

Each of the first and second connection vias 132 and 133 may include a metal. The metal may include at least one selected from the group consisting of copper (Cu), aluminum (Al), silver (Ag), tin (Sn), gold (Au), nickel (Ni), lead (Pb), titanium (Ti), and alloys thereof. Each of the first and second connection vias 132 and 133 may include a filled via filling a via hole, but may also include a conformal via disposed along a wall surface of the via hole. The first and second connection vias 132 and 133 may perform various functions depending on the design. For example, the first and second connection vias 132 and 133 may include a ground via, a power via, and a signal via. The first and second connection vias 132 and 133 may have tapered shapes opposite to each other in the cross-section. The first and second connection vias 132 and 133 may include an electroless plating layer (or chemical copper) and an electrolytic plating layer (or electrolytic copper). The first and second connection vias 132 and 133 may be provided in plural.

Each of the plurality of first and second build-up insulating layers 141 and 151 may include an organic insulating material. The organic insulating material may include a thermosetting resin such as an epoxy resin, a thermoplastic resin such as a polyimide, or a material including an inorganic filler, an organic filler, and/or glass fiber (glass fiber, glass cloth or glass fabric) together with these resins. For example, the organic insulating material may be a non-photosensitive insulating material such as Ajinomoto Build-up Film (ABF) or prepreg (PPG), but the present disclosure is not limited thereto, and other polymer materials may be used in addition thereto. Additionally, the organic insulating material may be a photosensitive insulating material such as photoimageable dielectric (PID). The plurality of first and second build-up insulating layers 141 and 151 may include substantially the same organic insulating material, but the present disclosure is not limited thereto. The plurality of first and second build-up insulating layers 141 and 151 may have the same number of layers, but the present disclosure is not limited thereto.

Each of the plurality of first and second build-up wiring layers 142 and 152 may include a metal. The metal included in the plurality of first and second build-up wiring layers 142 and 152 may include at least one selected from the group consisting of copper (Cu), aluminum (Al), silver (Ag), tin (Sn), gold (Au), nickel (Ni), lead (Pb), titanium (Ti), and alloys thereof. Each of the plurality of first and second build-up wiring layers 142 and 152 may perform various functions according to the design. For example, the plurality of first and second build-up wiring layers 142 and 152 may include a signal pattern, a power pattern, and a ground pattern. Each of the patterns may have various shapes such as a line, a plane, a pad, and the like. The plurality of first and second build-up wiring layers 142 and 152 may include an electroless plating layer (or chemical copper) and an electrolytic plating layer (or electrolytic copper). The plurality of first and second build-up wiring layers 142 and 152 may have the same number of layers, but the present disclosure is not limited thereto.

Each of the plurality of first and second build-up via layers 143 and 153 may include a metal. The metal included in the plurality of first and second build-up via layers 143 and 153 may include at least one selected from the group consisting of copper (Cu), aluminum (Al), silver (Ag), tin (Sn), gold (Au), nickel (Ni), lead (Pb), titanium (Ti), and alloys thereof. Each of the one or more first and second build-up via layers 143 and 153 may include a filled via filling a via hole, but may also include a conformal via disposed along a wall surface of the via hole. Each of the plurality of first and second build-up via layers 143 and 153 may perform various functions according to the design. For example, the plurality of first and second build-up via layers 143 and 153 may include a ground via, a power via, and a signal via. The plurality of first and second build-up via layers 143 and 153 may have tapered shapes in the cross-section. The plurality of first and second build-up via layers 143 and 153 may include an electroless plating layer (or chemical copper) and an electrolytic plating layer (or electrolytic copper). The plurality of first and second build-up via layers 143 and 153 may have the same number of layers, but the present disclosure is not limited thereto.

The first and second passivation layers 161 and 162 may include a liquid or film type solder resist, but are not limited thereto, and other types of insulating materials such as ABF may be used. A surface treatment layer and/or a metal bump may be formed on a pattern exposed through first and second openings 161h and 162h as needed. The pattern exposed through the first and second openings 161h and 162h may be solder mask defined (SMD) and/or non-solder mask defined (NSMD) shapes, but the present disclosure is not limited thereto. Each of the first and second openings 161h and 162h may be provided in plural.

Each of the first and second electrical connection metals 181 and 183 may be formed of a low melting point metal, for example, solder such as tin (Sn)-aluminum (Al)-copper (Cu), or the like, but this is only an example, and the material is not particularly limited thereto. Each of the first and second electrical connection metals 181 and 183 may be a ball shape, a pin shape, or the like. Each of the first and second electrical connection metals 181 and 183 may be formed of a multilayer or a single layer. When the first and second electrical connection metals 181 and 183 are formed of the multilayer, they may include a copper pillar and solder, and when the first and second electrical connection metals 181 and 183 are formed of the single layer, they may include tin-silver solder, but the present disclosure is not limited thereto. The first electrical connection metal 181 may be used for mounting electronic components 171 and 172, and the second electrical connection metal 182 may be used for mounting the printed circuit board 100A on another substrate such as a main board. Each of the first and second electrical connection metals 181 and 182 may be provided in plural.

Each of the first and second electronic components 171 and 172 may include an active component and/or a passive component. The active component may include various types of semiconductor chips, and the passive component may include various types of chip-type components such as chip capacitors or chip inductors. Each of the semiconductor chips may include an integrated circuit (IC) die in which at least several hundreds to several millions of elements are integrated into a single chip. In this case, the integrated circuit may be, for example, a logic chip such as a central processor (e.g., CPU), a graphics processor (e.g., GPU), a field programmable gate array (FPGA), a digital signal processor, an encryption processor, a microprocessor, a microcontroller, an application processor (e.g., AP), an analog-to-digital converter, an application-specific IC (ASIC), and the like, but is not limited thereto, and may be other types such as a memory chip such as a volatile memory (e.g., DRAM), a non-volatile memory (e.g., ROM), a flash memory or a high bandwidth memory (HBM), or a power management IC (PMIC).

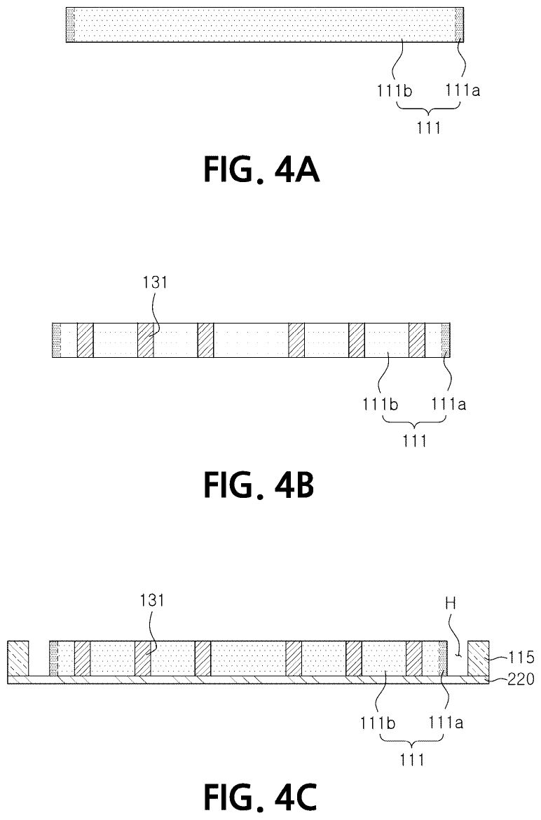

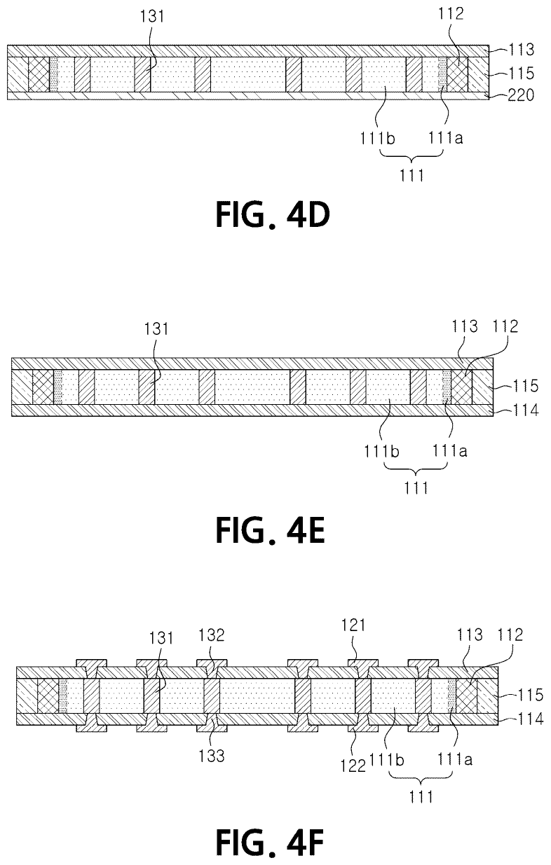

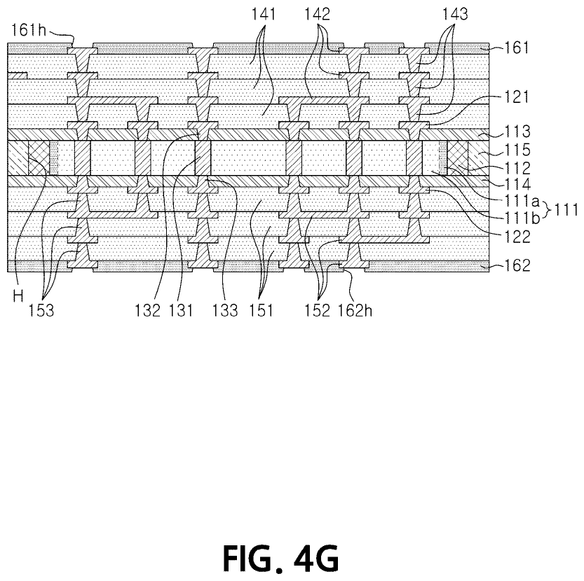

FIGS. 4A to 4G are process diagrams schematically illustrating an example of manufacturing the printed circuit board of FIG. 2.

Referring to FIG. 4A, a glass layer 111 may be prepared. The glass layer 111 may be in the form of a glass plate. Next, an edge region 111a of the glass layer 111 may be reinforced. For example, the glass layer 111 may be immersed in a KNO₃ solution, and heated to a high temperature in a state in which a surface of an inner area 111b of the glass layer 111 is covered with a masking tape, and then chemical reinforcing treatment may be performed by ion exchange, or the like.

Referring to FIG. 4B, at least one through-via 131 may be formed in the glass layer 111. The glass layer 11 may include a plurality of the through vias. For example, a through-hole may be formed in the glass layer 111 in various methods such as laser processing, mechanical processing, and chemical processing, and a seed layer may be formed on a wall surface of the through-hole by sputtering, or the like, and then the through-hole may be filled by electrolytic plating, or the like, thereby forming a through-via 131. A plating layer on the upper surface and the lower surface of the glass layer 111 may be removed by etching.

Referring to FIG. 4C, the glass layer 111 may be disposed in a through-hole H surrounded by a frame 115. For example, after a tape 220 for blocking a lower side of the through-hole H is attached to a lower side of the frame 115, the glass layer 111 may be attached onto the tape 220, unattached to the frame 115 to form the through-hole H. The frame 115 may include various materials such as a metal and an organic insulating material. The frame 115 may have a jig shape. The tape 220 may include polyimide (PI), but the material is not particularly limited thereto.

Referring to FIG. 4D, a remaining space of the through-hole H may be filled with the first insulating material 112. Additionally, the second insulating material 113 may be stacked on the upper side of the glass layer 111 and the first insulating material 112. If necessary, flattening may be performed. The first and second insulating materials 112 and 113 may be formed simultaneously by stacking an insulating layer on the frame 115 and the glass layer 111.

Referring to FIG. 4E, the tape 220 may be removed, and the third insulating material 114 may be stacked on the glass layer 111 from which the tape 220 has been removed, and a lower side of the first insulating material 112. If necessary, flattening may be performed.

Referring to FIG. 4F, after processing a via hole in the second and third insulating materials 113 and 114, a plating process may be performed to form the first and second wiring layers 121 and 122 and the first and second connection vias 132 and 133. The processing of the via hole may be performed using a laser processing, or the like. The plating process may be performed using an electroless plating and an electrolytic plating.

Referring to FIG. 4G, a build-up process and a plating process may be performed on the second and third insulating materials 113 and 114, respectively, thereby forming a plurality of first and second build-up insulating layers 141 and 151, a plurality of first and second build-up wiring layers 142 and 152, and a plurality of first and second build-up via layers 143 and 153. Additionally, first and second passivation layers 161 and 162 may be formed by a lamination process or a coating process. Then, if necessary, first and second electrical connection metals may be formed, and the first and second electronic components may be mounted. The printed circuit board 100A described above may be manufactured through a series of processes, and other contents may be substantially the same as described above.

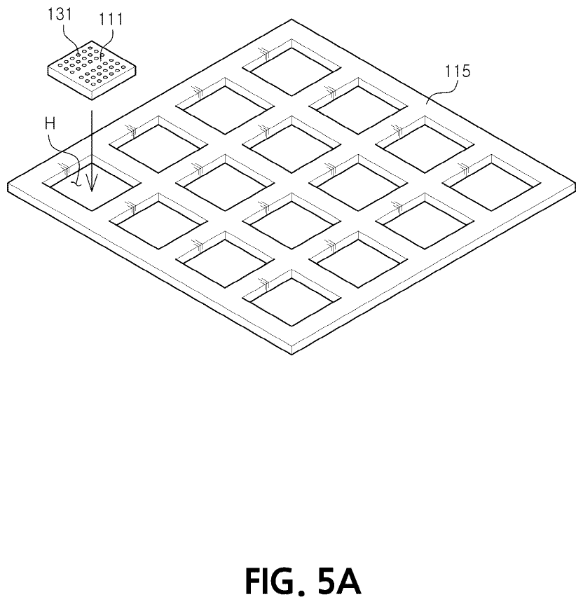

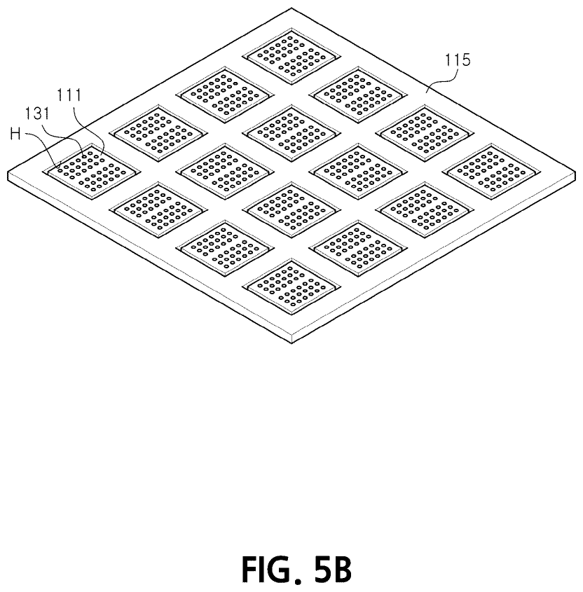

FIG. 5A and FIG. 5B are process diagrams schematically illustrating an example of arranging a plurality of glass layers 111 in a frame 115 having a plurality of through-portions.

Referring to the drawings, a frame 115 may have a plurality of through-portions H, and a plurality of glass layers 111 may be disposed in each of the plurality of through-portions H. Each of the plurality of glass layers 111 may be subject to the reinforcement treatment through the manufacturing processes of FIGS. 4A to 4C described above and may have a through-via 131 formed thereon, and may be disposed in each of the plurality of penetrations H using tape. Then, the manufacturing processes of FIGS. 4D to 4G described above may be performed to manufacture a plurality of printed circuit board 100A units, and a plurality of printed circuit boards 100A may be obtained through a singulation process. For example, the plurality of printed circuit boards 100A may be manufactured through a process on the panel level. Other contents may be substantially the same as those described in the printed circuit board 100A described above and a manufacturing method thereof.

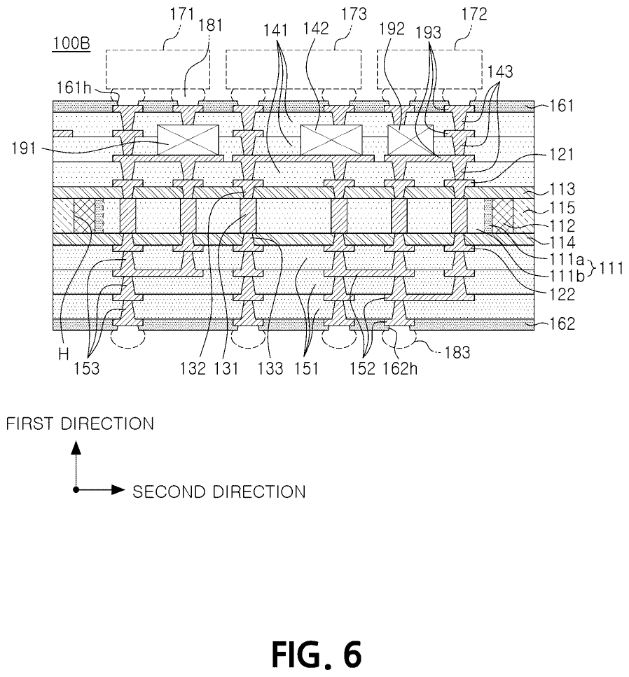

FIG. 6 is a cross-sectional view schematically illustrating another example of a printed circuit board.

Referring to FIG. 6, a printed circuit board 100B may further include a third electronic component 173 mounted on the first passivation layer 161 through the first electrical connection metal 181, in the printed circuit board 100A described above. Additionally, the printed circuit board 100B may further include first to third electronic elements 191, 192 and 193 respectively embedded in a plurality of first build-up insulating layers 141, and respectively connected to at least a portion of at least one of the plurality of first build-up wiring layers 142 through at least a portion of at least one of the plurality of first build-up via layers 143. The third electronic component 173 may include an active component and/or a passive component. Each of the first to third electronic components 191, 192 and 193 may include an interconnect bridge, an active component, and/or a passive component. The interconnect bridge may transmit an electrical signal between at least two of the first to third electronic components 171, 172 and 173 through an internal high-density circuit. The interconnect bridge may be a silicon bridge, an organic bridge, or the like. The active component may include various types of semiconductor chips, and the passive component may include various types of chip-type components such as a chip capacitor or a chip inductor. Other contents may be substantially the same as those described in the printed circuit board 100A described above and a manufacturing method thereof.

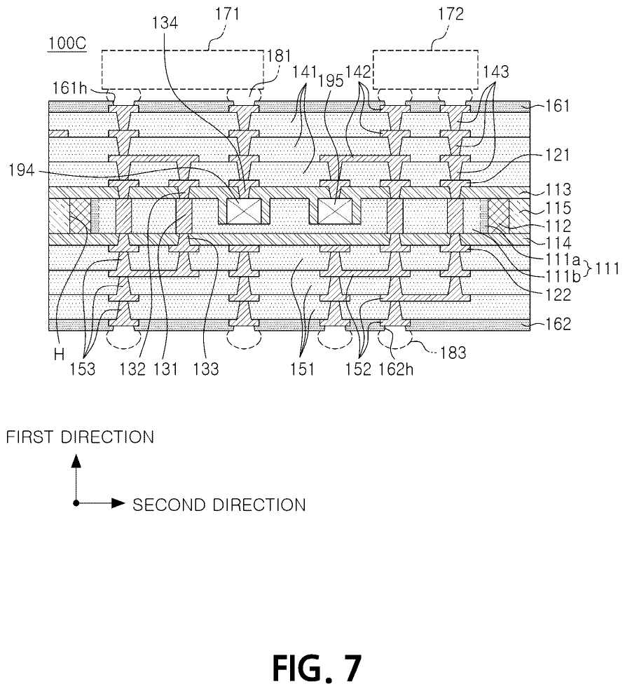

FIG. 7 is a cross-sectional view schematically illustrating another example of a printed circuit board.

Referring to FIG. 7, a printed circuit board 100C may further include fourth and fifth electronic elements 194 and 195 embedded in a core layer, more specifically, the glass layer 111, in the printed circuit board 100A described above. For example, the fourth and fifth electronic elements 194 and 195 may be respectively disposed in cavities formed in the glass layer 111, and may be respectively connected to at least a portion of the first wiring layer 121 through a third connection via 134 penetrating through the second insulating material 113. The cavity may be a blind cavity penetrating through a portion of the upper surface of the glass layer 111, but may also be a through-cavity penetrating between the upper surface and the lower surface of the glass layer 111. Each of the fourth and fifth electronic components 194 and 195 may include an active component and/or a passive component. The active component may include various types of semiconductor chips, and the passive component may include various types of chip-type components such as a chip capacitor or a chip inductor. Other contents may be substantially the same as those described in the printed circuit board 100A described above and a manufacturing method thereof.

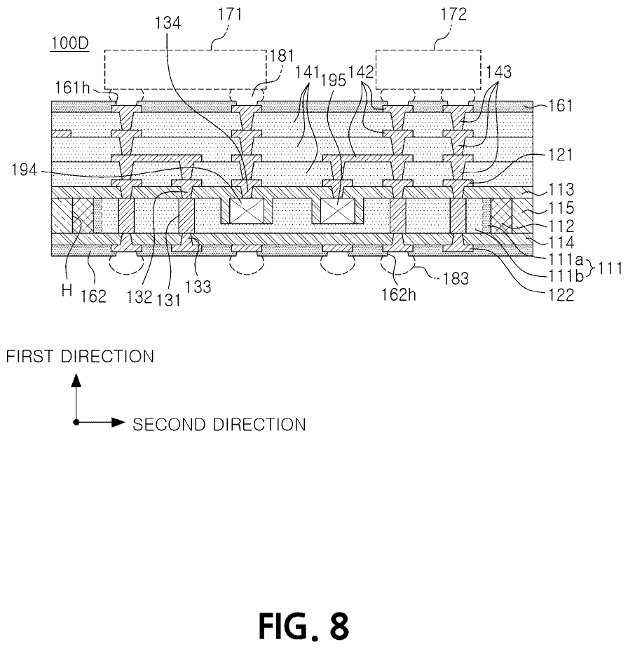

FIG. 8 is a cross-sectional view schematically illustrating another example of a printed circuit board.

Referring to FIG. 8, a printed circuit board 100D may be configured so that a plurality of second build-up insulating layers 151, a plurality of second build-up wiring layers 152, and a plurality of second build-up via layers 153 may be omitted, in the printed circuit board 100C described above. For example, the printed circuit board 100D may have an asymmetrical structure built up only on an upper side based on a core layer. Meanwhile, the technical characteristics of the printed circuit board 100D may be applied not only to the printed circuit board 100C described above, but also to the printed circuit boards 100A and 100B described above. Other contents may be substantially the same as those described in the printed circuit boards 100A, 100B and 100C described above and manufacturing methods thereof.

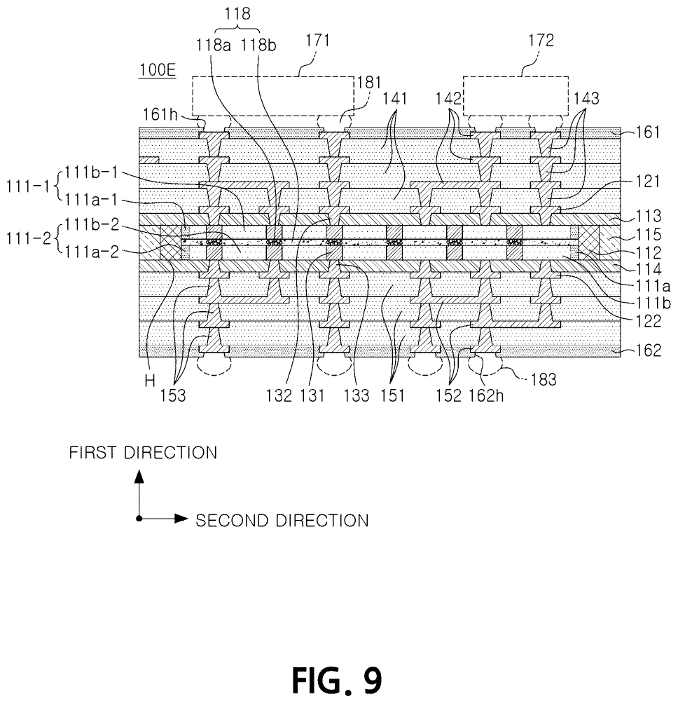

FIG. 9 is a cross-sectional view schematically illustrating another example of a printed circuit board.

Referring to FIG. 9, a printed circuit board 100E may include first and second glass layers 111-1 and 111-2 spaced apart from each other in the first direction, in the printed circuit board 100A described above. Additionally, the through-via 131 may include a first through-via 131-1 penetrating through the first glass layer 111-1 and a second through-via 131-2 penetrating through the second glass layer 111-2. Additionally, a conductive film 118 including conductive particles 118a electrically connecting the first and second through-vias 131-1 and 131-2 may be disposed between the first and second glass layers 111-1 and 111-2. For example, when a thicker glass layer 111 is required in the core layer, such a structure may be introduced. The first glass layer 111-1 may include a reinforced first edge region 111a-1 and a reinforced first internal region 111b-1. The second glass layer 111-2 may include a reinforced second edge region 111b-1 and a reinforced second internal region 111b-2. The conductive film 118 may include conductive particles 118a and an insulating resin 118b. The conductive particles 118a may be metal particles. The conductive film 118 may include an anisotropic conductive film (ACF), but the present disclosure is not limited thereto. Meanwhile, the technical characteristics of the printed circuit board 100E may be applied not only to the above-described printed circuit board 100A, but also to the above-described printed circuit boards 100B, 100C and 100D. Other contents may be substantially the same as those described in the above-described printed circuit boards 100A, 100B, 100C and 100D and manufacturing methods thereof.

In the present disclosure, a thickness, a width, a length, a pitch, a depth, and the like, may be measured using a scanning microscope, an optical microscope, or the like, based in the cross-section obtained by polishing or cutting a printed circuit board, respectively. The cut cross-section may be a vertical cross-section or a horizontal cross-section, and each value may be measured based on a required cut cross-section. When the value is not constant, the value may be determined as an average value of values measured at five arbitrary points. A width of an upper portion and/or a lower portion of a via may be measured in the cross-section obtained by cutting a substrate along a central axis of a via in a thickness direction. A depth of the via may be measured as the distance from an upper portion to a lower portion of the via in the cross-section obtained by cutting the substrate along the central axis of the via in the thickness direction.

In the present disclosure, the expression “covering” may include a case of covering at least a portion as well as a case of covering the whole, and may also include a case of covering not only directly but also indirectly. Furthermore, the expression “filling” may include not only a case of completely filling but also a case of at least partially filling, and may also include a case of approximately filling. For example, this may include a case in which some pores or voids exist.

In the present disclosure, determination may be performed by including process errors, positional deviations, errors at the time of measurement, which may occur substantially in a manufacturing process. For example, substantially the same as a line width, a gap, a thickness, a height, and the like, may include not only completely the same as numbers, but also having approximately similar numbers. Furthermore, substantially having a certain shape may include not only completely having that shape, but also having approximately that shape. Furthermore, substantially being coplanar may include not only completely being in the same plane, but also approximately being in the same plane.

In the present disclosure, the same insulating material may denote not only a case of being the same insulating material, but also a case of including the same type of insulating material. Accordingly, the composition of the insulating material is substantially the same, but specific composition ratios thereof may be slightly different.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression “example embodiment used in the present disclosure” does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a glass layer including:
an upper surface and a lower surface opposing each other in a first direction;
a first side surface and a second side surface opposing each other in a second direction, perpendicular to the first direction;
a third side surface and a fourth side surface opposing each other in a third direction, perpendicular to the first and second directions;
a reinforced region at at least a part of an edge region of the glass layer which is adjacent to each of the first to fourth side surfaces; and
an inner region having not be reinforced at an area surrounded by the edge region;
a first insulating material covering at least portions of the first to fourth side surfaces of the glass layer; and
second and third insulating materials covering at least a portion of each of the upper surface and the lower surface of the glass layer and extending to an upper side and a lower side of the first insulating material, respectively.

2. The printed circuit board according to claim 1,
wherein the reinforced region of the glass layer includes first and second metal ions, and
wherein the second metal ion has a larger ionic radius than the first metal ion.

3. The printed circuit board according to claim 2,
wherein the first metal ion includes Na⁺ ions, and the second metal ion includes K⁺ ions.

4. The printed circuit board according to claim 1,
wherein the reinforced region of the glass layer is a region having a depth of 50 μm to 100 μm from each of the first to fourth side surfaces based on the second or third direction.

5. The printed circuit board according to claim 1,
wherein the first to third insulating materials include insulating layers in which boundaries thereof are separated from each other, and
an upper surface and a lower surface of the first insulating material are substantially coplanar with the upper surface and lower surface of the glass layer.

6. The printed circuit board according to claim 1,
wherein one or more of the second and third insulating materials is integrated with the first insulating material without boundaries to form one insulating layer.

7. The printed circuit board according to claim 1, further comprising:
a frame having a through-portion in which the glass layer is disposed,
wherein the first insulating material fills at least a space between each of the first to fourth side surfaces of the glass layer and an inner wall surface of the frame, and
the second and third insulating materials extend to an upper side and a lower side of the frame, respectively.

8. The printed circuit board according to claim 1, further comprising:
a through-via penetrating between the upper surface and the lower surface of the glass layer;
a first connection via penetrating through the second insulating material and connected to an upper side of the through-via;
a second connection via penetrating through the third insulating material and connected to a lower side of the through-via;
a first wiring layer disposed on an upper surface of the second insulating material and at least partially connected to the first connection via; and
a second wiring layer disposed on a lower surface of the third insulating material and at least partially connected to the second connection via.

9. The printed circuit board according to claim 8,
wherein the through-via includes a first seed layer comprising sputtered titanium and sputtered copper, and
each of the first and second connection vias a second seed layer including chemical copper.

10. The printed circuit board according to claim 8, further comprising:
a first electronic element embedded in the glass layer; and
a third connection via penetrating through the second insulating material, and connecting the first electronic component to at least another portion of the first wiring layer,
wherein the first electronic component includes one or more of an active component and a passive component.

11. The printed circuit board according to claim 1, wherein the glass layer includes first and second glass layers spaced apart from each other in the first direction,
the through-via includes a first through-via penetrating through the first glass layer and a second through-via penetrating through the second glass layer, and
a conductive film including conductive particles electrically connecting the first and second through-vias is disposed between the first and second glass layers.

12. The printed circuit board according to claim 8, further comprising:
a plurality of first build-up insulating layers stacked on an upper surface of the second insulating material;
a plurality of first build-up wiring layers disposed on each of upper surfaces of the plurality of first build-up insulating layers or in each of the plurality of first build-up insulating layers; and
a plurality of first build-up via layers disposed in each of the plurality of first build-up insulating layers.

13. The printed circuit board according to claim 12, further comprising:
a second electronic component embedded in the plurality of first build-up insulating layers, and connected to at least a portion of at least one of the plurality of first build-up wiring layers via at least a portion of at least one of the plurality of first build-up via layers,
wherein the second electronic component includes one or more of an interconnect bridge, an active component, and a passive component.

14. The printed circuit board according to claim 12, further comprising:
a first passivation layer disposed on an upper surface of a first build-up insulating layer disposed on an uppermost side, among the plurality of first build-up wiring layers, and having a first opening exposing at least a portion of the first build-up wiring layer disposed on an uppermost side, among the plurality of first build-up wiring layers;
a second passivation layer disposed on a lower surface of the third insulating material, and having an opening exposing at least a portion of the second wiring layer;
a first electrical connection metal disposed on the first opening, and connected to the at least exposed portion of the first build-up wiring layer disposed on the uppermost side;
an electronic component mounted on an upper surface of the first passivation layer and connected to the first electrical connection metal; and
a second electrical connection metal disposed on the second opening and connected to the at least exposed portion of the second wiring layer,
wherein the electronic component includes one or more of an active component and a passive component.

15. The printed circuit board according to claim 12, further comprising:
a plurality of second build-up insulating layers stacked on the lower surface of the third insulating material;
a plurality of second build-up wiring layers respectively disposed on lower surfaces of the plurality of second build-up insulating layers or in the plurality of second build-up insulating layers; and
a plurality of second build-up via layers respectively disposed in the plurality of second build-up insulating layers.

16. The printed circuit board according to claim 15, further comprising:
a first passivation layer disposed on an upper surface of a first build-up insulating layer disposed on an uppermost side, among the plurality of first build-up insulating layers, and having a first opening exposing at least a portion of a first build-up wiring layer disposed on an uppermost side, among the plurality of first build-up wiring layers;
a second passivation layer disposed on a lower surface of a second build-up insulating layer disposed on a lowermost side, among the plurality of second build-up wiring layers, and having a second opening exposing at least a portion of the second build-up wiring layer disposed on the lowermost side, among the plurality of second build-up wiring layers;
a first electrical connection metal disposed on the first opening and connected to the at least exposed portion of the first build-up wiring layer disposed on the uppermost side;
an electronic component mounted on an upper surface of the first passivation layer and connected to the first electrical connection metal; and
a second electrical connection metal disposed on the second opening and connected to the at least exposed portion of the second build-up wiring layer disposed on the lowermost side.

17. A printed circuit board, further comprising:
a frame having a through-portion;
a glass layer disposed on the through-portion and configured to reinforce at least a portion of an edge region adjacent to a plurality of side surfaces connecting an upper surface and a lower surface thereof; and
an insulating material filling at least a portion of the through-portion and covering at least a portion of each of the frame and the glass layer.

18. The printed circuit board according to claim 17,
wherein the frame includes a copper clad laminate (CCL) or an unclad CCL.

19. A printed circuit board, comprising:
a glass layer,
a frame having a through-portion in which the glass layer is disposed,
a first insulating material disposed a space between a side surface of the glass layer and an inner side surface of the frame, and
a second insulating material disposed on at least a part of an upper surface of the glass layer and at least a part of an upper surface of the first insulating material,
a third insulating material disposed on at least a part of a lower surface of the glass layer and at least a part of a lower surface of the first insulating material,
wherein the glass layer includes a reinforced region at a side edge region of the glass layer which faces against the inner side surface of the frame.

20. The printed circuit board according to claim 19,
wherein the reinforced region of the glass layer includes first and second metal ions, and
wherein the second metal ion has a larger ionic radius than the first metal ion.
